(19) United States
(12) Patent Application Publication
(10) Pub. No.: US 2025/0133765 A1
(43) Pub. Date: Apr. 24, 2025

(54) DRAM DEVICE COMPRISING SWITCHING INSULATING LAYER

(71) Applicant: TAESUNG ENVIRONMENTAL RESEARCH INSTITUTE CO., LTD., Ulsan (KR)

(72) Inventors: Gi Yeol YUN, Ulsan (KR); Seok Man Kim, Ulsan (KR); Chai Rok Lim, Ulsan (KR); Hyeok-je Jeong, Gimhae-si (KR); Myung-Kon Jo, Ulsan (KR)

(73) Assignee: TAESUNG ENVIRONMENTAL RESEARCH INSTITUTE CO., LTD., Ulsan (KR)

(21) Appl. No.: 18/678,983

(22) Filed: May 30, 2024

(30) Foreign Application Priority Data
Oct. 20, 2023 (KR) 10-2023-0141178
Nov. 28, 2023 (KR) 10-2023-0168223

(51) Int. Cl. H01L 29/78; H01L 29/423; H10B 12/00

(52) U.S. Cl. CPC H10D 30/63; H10B 12/482; H10B 12/488; H10D 64/514

(57) ABSTRACT

A semiconductor device, comprising: a substrate; a plurality of bit lines located on the substrate, and disposed parallel to each other in a first horizontal direction; a plurality of word lines located on the bit line, and disposed parallel to each other in a second horizontal direction substantially perpendicular to the first horizontal direction; a plurality of channel patterns arranged in an array on the bit line, the plurality of channel patterns; a gate insulating pattern located between the plurality of channel patterns and the plurality of word lines; a plurality of switching insulating layers each formed on an upper surface of each of the plurality of channel patterns, at least a portion of which has a thickness that an electron can penetrate upon application of a voltage; and a plurality of control electrodes disposed parallel to each other to connect the plurality of switching insulating layers, is disclosed.

### TECHNICAL FIELD

The present invention relates to a semiconductor device. More specifically, the present invention relates to a semiconductor device comprising a vertical channel transistor.

### BACKGROUND ART

As the density of semiconductor memory devices increases, the cell structure is changing from 8F2 and 6F2 to 4F2 in order to reduce the area occupied by each unit cell in a planar plane. As such, various methods have been suggested to form components such as transistors, bit lines, word lines, capacitors, etc. in response to the decrease in the area of the unit cell. In particular, in order to implement a 4F2 cell structure, a semiconductor device comprising a vertical channel transistor that induces a vertical channel by disposing a source and a drain vertically has been suggested (non-patent reference 1).

However, in the semiconductor device of non-patent reference 1, the vertical pillar is in direct contact with the cell capacitor, causing leakage current to flow during data storage. Accordingly, the semiconductor device has a short retention time, requiring frequent data refresh operations and high power consumption.

### Prior Art Reference

### Non-Patent Reference

(Non-patent reference 1) Chung et al., “Novel 4F2 DRAM Cell with Vertical Pillar Transistor (VPT)”2011 Proceedings of the European Solid-State Device Research Conference (ESSDERC), 2011

### SUMMARY OF INVENTION

### Technical Task

One of the many objects of the present invention is to provide a vertical channel transistor capable of extending retention time and a semiconductor device comprising the same.

### Means for Solving Technical Task

According to an aspect, a semiconductor device, comprising: a substrate; a plurality of bit lines located on the substrate, and disposed parallel to each other in a first horizontal direction at predetermined intervals; a plurality of word lines located on the bit line, and disposed parallel to each other in a second horizontal direction substantially perpendicular to the first horizontal direction at predetermined intervals; a plurality of channel patterns arranged in an array on the bit line, the plurality of channel patterns each extending in a vertical direction; a gate insulating pattern located between the plurality of channel patterns and the plurality of word lines; a plurality of switching insulating layers each formed on an upper surface of each of the plurality of channel patterns, at least a portion of which has a thickness that an electron can penetrate upon application of a voltage; and a plurality of control electrodes disposed parallel to each other at predetermined intervals to connect the plurality of switching insulating layers, is disclosed.

In an embodiment, the plurality of control electrodes may be disposed parallel to each other in the second horizontal direction.

In an embodiment, the control electrode may have a thickness greater than the thickness of the switching insulating layer.

In an embodiment, the switching insulating layer may comprise at least one selected from the group consisting of silicon oxide (SiO₂), titanium oxide (TiO₂), aluminum oxide (Al₂O₃), nickel oxide (NiO, NiO₂, Ni₂O₃), copper oxide (Cu₂O, CuO), zirconium oxide (ZrO₂), manganese oxide (MnO, MnO₂, Mn₂O₃, Mn₃O₄, Mn₂O₇), hafnium oxide (HfO₂), tungsten oxide (WO, WO₂, WO₃, W₂O₃), tantalum oxide (Ta₂O₅), niobium oxide (Nb₂O₅) and iron oxide (FeO, Fe₂O₃, Fe₃O₄).

In an embodiment, the semiconductor device may further comprise a spacer layer formed on at least a portion of a side surface of the plurality of channel patterns to electrically insulate the plurality of channel patterns from the plurality of control electrodes.

In an embodiment, each of the plurality of channel patterns may comprise an upper electrode and a lower electrode, wherein the lower electrode may be in contact with the bit line.

In an embodiment, the semiconductor device may further comprise a gate electrode arranged between the word line and the gate insulating pattern.

### Effect of Invention

The semiconductor device according to an aspect of the present invention suppresses leakage current generation and extends retention time

In addition, the semiconductor device according to an aspect of the present invention has excellent data retention characteristics and low power consumption.

The effects of an aspect of the present specification are not limited to the above-mentioned effects, and it should be understood that the effects of the present specification include all effects that could be inferred from the configuration described in the detailed description of the specification or the appended claims.

### BRIEF DESCRIPTION OF DRAWINGS

FIG. 1 is a perspective view of a vertical channel transistor according to an embodiment of the present invention;

FIG. 2 is a cross-sectional view taken along A-A′ of FIG. 1;

FIG. 3 is a perspective view of a semiconductor device comprising the vertical channel transistor of FIG. 1;

FIG. 4 is a cross-sectional view of a vertical channel transistor according to a first modification example; and

FIG. 5 illustrates an energy band inside a switching insulating layer.

### BEST MODE FOR CARRYING OUT THE INVENTION

Hereinafter, an aspect of the present invention will be explained with reference to the accompanying drawings. However, the present invention may be implemented in various different forms, and is not intended to be limited to the embodiments set forth herein.

Throughout the specification, it will be understood that when a portion is referred to as being “connected” to another portion, it can be “directly connected to” the other portion, or “indirectly connected to” the other portion having intervening portions present. In addition, when a member is referred to as being located “on,” “on an upper part of,” “on an upper end of,” “under,” “on a lower part of,” “on a lower end of” another member, this includes not only when a member is adjacent to another member, but also when there is another member between the two members.

Throughout this specification, when a component “includes” an element, unless there is another opposite description thereto, it should be understood that the component does not exclude another element but may further include another element.

The embodiments described herein will be described with reference to the cross-sectional views and/or schematic drawings, which are idealized illustrations of the present invention. In addition, throughout the specification, like reference numerals refer to like components. Detailed descriptions of known features and configurations which may obscure the gist of the present invention are hereby omitted, and each component in each of the drawings illustrating the present invention may be somewhat enlarged or reduced in size for ease of description.

Further, embodiments of the present invention are not limited to specific shapes illustrated, but also include variations in shape produced by the manufacturing process.

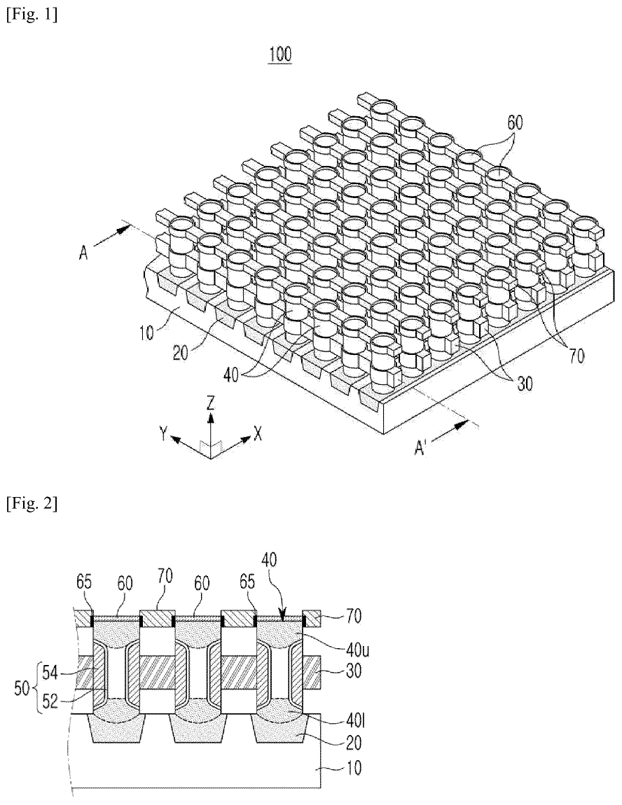

FIG. 1 is a perspective view of a vertical channel transistor according to an embodiment of the present invention.

Referring to FIG. 1, a vertical channel transistor 100 according to an embodiment of the present invention comprises: a substrate 10; a plurality of bit lines 20 located on the substrate 10, and disposed parallel to each other in a first horizontal direction at predetermined intervals; a plurality of word lines 30 located on the bit line 20, and disposed parallel to each other in a second horizontal direction substantially perpendicular to the first horizontal direction at predetermined intervals; a plurality of channel patterns 40 arranged in an array on the bit line 20, the plurality of channel patterns each extending in a vertical direction; a gate insulating pattern (not shown) located between the plurality of channel patterns 40 and the plurality of word lines 30; a plurality of switching insulating layers 60 each formed on an upper surface of each of the plurality of channel patterns 40, at least a portion of which has a thickness that an electron can penetrate upon application of a voltage; and a plurality of control electrodes 70 disposed parallel to each other at predetermined intervals to connect the plurality of switching insulating layers 60.

The vertical channel transistor 100 according to an embodiment of the present invention has a plurality of bit lines 20 and a plurality of word lines 30 intersect each other. Each bit line 20 may extend in a first horizontal direction (e.g., an X-axis direction), and each word line 30 may extend in a second horizontal direction (e.g., a Y-axis direction) intersecting the first horizontal direction.

A plurality of channel patterns 40 are disposed at the points where the plurality of bit lines 20 and the plurality of word lines 30 intersect.

Electrodes (not shown) are formed, respectively, at an upper part and a lower part of the plurality of channel patterns 40. Agate (not shown) is formed to enclose a side surface between the upper electrode and the lower electrode, and the gate may comprise a gate insulating pattern and a gate conducing pattern.

FIG. 2 is a cross-sectional view taken along A-A′ of FIG. 1.

Referring to FIG. 2, the vertical channel transistor 100 comprises a substrate 10 and a plurality of channel patterns 40 arranged in an array on the substrate 10. The channel patterns 40 may be arranged in a two-dimensional array on a plane (e.g., an XY plane) of the substrate 10.

The substrate may include, for example, a group IV semiconductor material such as silicon (Si), germanium (Ge), silicon germanium (SiGe), silicon carbide (SiC), a group III-V semiconductor material such as gallium arsenide (GaAs), indium arsenide (InAs), indium phosphide (InP), an oxide semiconductor, a nitride semiconductor, a nitrogen oxide semiconductor, etc. Specifically, the substrate may be a silicon substrate doped with n-type impurities, but is not limited thereto.

Each of the plurality of channel patterns 40 may extend substantially vertically from the substrate 10. Here, each channel pattern 40 may protrude substantially vertically from an upper surface of the substrate 10. Each channel pattern 40 is integrally formed with the substrate 10, and thus may comprise the same semiconductor material as the substrate 10.

Each of the plurality of channel patterns 40 may comprise a source region as an upper electrode 40u and a drain region as a lower electrode 40l. The lower electrode 40l may be electrically connected to the bit line 20, and the upper electrode 40u may be electrically connected to a capacitor (not shown) which will be described later. The positions of the source region and the drain region may vary as needed, and the upper electrode 40u may function as a drain region and the lower electrode 40l may function as a source region.

In the channel pattern 40, the region between the upper electrode 40u and the lower electrode 40l, which is the body region (not shown), has the same polarity as the substrate 10, and the upper electrode 40u and the lower electrode 40l have a different polarity from the substrate 10. For example, when the substrate 10 is a p-type semiconductor substrate, the body region has a p-type polarity, and the upper electrode 40u and the lower electrode 40l have an n-type polarity. In this case, the upper electrode 40u and the lower electrode 40l may be formed by implanting n-type impurity ions into each of the upper end and the lower end of the channel pattern 40 and performing drive-in diffusion.

Agate 50 is formed between the upper electrode and the lower electrode to enclose a side surface of the channel pattern 40, and the gate 50 may comprise a gate insulating pattern 52 and a gate conducing pattern 54.

In an example, at least a portion of each channel pattern 40 may be in direct contact with the substrate 10. In this case, a back bias may be imparted to each channel pattern 40 to suppress the floating body effect. The contact area of each channel pattern 40 with the substrate 10 is not particularly limited, but may be, for example, any one of a periphery part or a center part of each channel pattern 40.

The bit lines 20 are arranged to extend along a first horizontal direction (e.g., an X-axis direction) on a lower part of the lower electrode 40l, and each bit line 20 may electrically connect the lower electrode 40l arranged along the first horizontal direction. The bit line 20 is formed in the interior of the substrate 10, and thus may comprise the same semiconductor material as the substrate 10.

Each of the plurality of word lines 30 is provided to correspond to a gate 50 formed on a side surface of the channel pattern 40. Specifically, each word line 30 may be provided to enclose the gate 50.

The word line 30 may comprise a conductive material. For example, the word line 30 may comprise at least one of metal, semiconductor and alloy. Specifically, the word line 30 may comprise one or more metals selected from the group consisting of aluminum, tungsten, molybdenum, titanium, and tantalum, and one or more semiconductors selected from the group consisting of group IV semiconductors, group III-V semiconductors, oxide semiconductors, nitride semiconductors, and nitrogen oxide semiconductors, but is not limited thereto.

A plurality of switching insulating layers 60 are each formed on an upper surface of each of the plurality of channel patterns 40, at least a portion of which has a thickness that an electron can penetrate upon application of an external voltage.

According to conventional vertical channel transistors, the channel pattern is in direction contact with the cell capacitor, causing leakage current to flow during data storage. Accordingly, the semiconductor device has a short retention time, requiring frequent data refresh operations.

However, according to the present invention, the switching insulating layer 60 is formed on the upper surface of the channel pattern 40. Accordingly, current flows between the channel pattern and the capacitor by tunneling, channeling, etc., upon application of an external voltage during data recognition, whereas leakage current generation is suppressed during data storage, resulting in extended retention time. Thereby, cells can normally operate during data storage and during data recognition, data retention characteristics are improved, and also power consumption can be reduced. In addition, extended retention time allows a cell capacitor to have a smaller height, which facilitates manufacturing and scaling down.

The switching insulating layer 60 may comprise, but is not limited to, at least one selected from the group consisting of silicon oxide (SiO₂), titanium oxide (TiO₂), aluminum oxide (Al₂O₃), nickel oxide (NiO, NiO₂, Ni₂O₃), copper oxide (Cu₂O, CuO), zirconium oxide (ZrO₂), manganese oxide (MnO, MnO₂, Mn₂O₃, Mn₃O₄, Mn₂O₇), hafnium oxide (HfO₂), tungsten oxide (WO, WO₂, WO₃, W₂O₃), tantalum oxide (Ta₂O₅), niobium oxide (Nb₂O₅) and iron oxide (FeO, Fe₂O₃, Fe₃O₄).

The thickness of the switching insulating layer 60 is not particularly limited as long as it can provide a pathway for electrons to move by tunneling, channeling, etc. The switching insulating layer 60 may have a thickness, e.g., 1 nm or less.

The plurality of control electrodes 70 are disposed parallel to each other at predetermined intervals to connect the plurality of switching insulating layers 60. The plurality of control electrodes 70 may be formed to enclose a side surface of each switching insulating layer 60. The plurality of control electrodes 70, which are for controlling the movement of electrons through the switching insulating layer, modify an energy band of the switching insulating layer 60 during data recognition, thereby helping electrons to move by tunneling, channeling, etc.

In the case where only the switching insulating layer 60 is formed between the channel pattern 40 and the capacitor, sufficient current flow can hardly be expected during data recognition. However, according to the present invention, a plurality of control electrodes 70 connecting the plurality of switching insulating layers 60 are arranged, and current is applied to the plurality of control electrodes 70 during data recognition, thereby achieving smooth current flow.

In an example, a plurality of control electrodes 70 may be disposed parallel to each other in a second horizontal direction. In other words, the plurality of control electrodes 70 may extend in the same direction as a plurality of word lines 30. In this case, the flow of current can be controlled smoothly by applying current to control electrodes arranged on word lines to which current is applied, while not applying current to control electrodes arranged on word lines to which current is not applied.

In an example, the control electrode 70 may have a thickness greater than the thickness of the switching insulating layer 60, e.g., a thickness of greater than 1 nm and 2 nm or less, but is not limited thereto. In this case, electrons in the switching insulating layer 60 may move smoothly by tunneling, channeling, etc.

In an example, a spacer layer 65 may be further comprised, which is formed on at least a portion of a side surface of the plurality of channel patterns 40 (e.g., an upper part of the channel pattern 40) to electrically insulate the plurality of channel patterns 40 from the plurality of control electrodes 70. The spacer layer 65 may extend to at least a portion of a side surface of the switching insulating layer 60, but is not limited thereto.

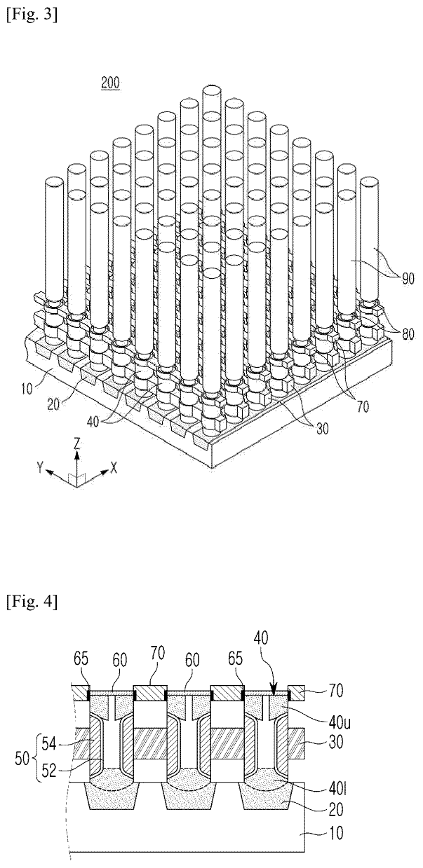

FIG. 3 is a perspective view of a semiconductor device comprising the vertical channel transistor of FIG. 1.

Referring to FIG. 3, a capacitor 90 is connected on the vertical channel transistor 100, through which a semiconductor device 200 such as a DRAM may be implemented.

The capacitor 90 may be electrically connected to the channel pattern 40, and a contact plug 80 may be further comprised between the capacitor 90 and the channel pattern 40. The vertical channel transistor 100 may be utilized in a non-memory such as a central processing unit (CPU), as well as in a memory as described above.

The present invention is not particularly limited to methods for manufacturing a vertical channel transistor and a semiconductor device comprising the same, but they may be manufactured by, for example, the following method.

On the substrate 10, a plurality of channel patterns 40 having electrodes 40u and 401 formed at an upper part and a lower part thereof and extending in a substantially vertical direction are formed. The upper electrode 40u of the plurality of channel patterns may be, for example, a source region, and the lower electrode 40l of the plurality of channel patterns may be, for example, a drain region.

The plurality of channel patterns 40 may be arranged in a two-dimensional array on a plane (e.g., an XY plane) of the substrate 10. Specifically, the channel patterns 40 may be arranged in a two-dimensional array equally spaced apart in first and second horizontal directions (e.g., in X-axis and Y-axis directions) on a plane (e.g., an XY plane) of the substrate 10.

Next, a gate 50 is formed to enclose a side surface between the upper electrode 40u and the lower electrode 40l of the plurality of channel patterns 40. The gate 50 may comprise a gate insulating pattern 52 and a gate conducing pattern 54.

Next, a plurality of bit lines 20 are formed to be in common contact with the lower electrode 40l of the plurality of channel patterns 40. Here, the bit lines 20 may be formed in a first horizontal direction (e.g., an X-axis direction).

Next, a plurality of word lines 30 are formed to be in common contact with the gate 50 formed on a side surface of the plurality of channel patterns 40. Here, the word lines 30 may be formed in a second horizontal direction (e.g., a Y-axis direction).

Next, a plurality of switching insulating layers 60 are each formed on an upper surface of each of the plurality of channel patterns 40, at least a portion of which has a thickness that an electron can penetrate upon application of an external voltage. Here, the thickness that an electron can penetrate upon application of an external voltage may be 1 nm or less, but is not limited thereto.

Next, a spacer layer 65 is formed on at least a portion of a side surface of the plurality of channel patterns 40 (e.g., an upper part of the channel pattern 40). The spacer layer 65 may extend to at least a portion of a side surface of the switching insulating layer 60, but is not limited thereto. The spacer layer 65 may electrically insulate the plurality of channel patterns 40 from a plurality of control electrodes 70.

Next, a plurality of control electrodes 70 are formed to be in common contact with the plurality of switching insulating layer 60. Here, the control electrode 70 may be formed in the same direction as the word line 30, i.e., in the second horizontal direction.

Thereafter, a series of subsequent processes known in the art may be performed one after the other to complete the manufacturing of a vertical channel transistor according to the present invention and a semiconductor device comprising the same.

### First Modification Example

FIG. 4 is a cross-sectional view of a vertical channel transistor according to a first modification example. In FIG. 4, like reference numerals indicate like components in the embodiment described above, and detailed descriptions thereon are omitted or simplified.

The first modification example is characterized in that the body region of the channel pattern 40 penetrates at least a portion of the upper electrode 40u, to be in direct contact with the switching insulating layer 60. In this case, the floating of the switching insulating layer 60 may be avoided.

The body region that penetrates the upper electrode 40u may be formed by an implantation process after forming the upper electrode 40u, or formed by disposing a mask having a predetermined opening pattern on the body region when forming the upper electrode 40u, and then implanting n-type impurity ions thereinto and performing drive-in diffusion.

The contact area of the body region and the switching insulating layer 60 is not particularly limited, but may be, for example, any one of a periphery part and a center part of each channel pattern 40.

The technical reasons why smooth current flow can be achieved by applying current to a control electrode are described in more details below.

First, for the case where only the switching insulating layer is formed between the channel pattern and the capacitor, a change in current density according to a potential difference between the channel pattern and the capacitor is described below.

The current-voltage characteristics for the physical thicknesses of the SiO₂ layer that is widely used as an insulating layer in the field of DRAM devices are illustrated in FIG. 1.1 in the paper (Muhammad Mustafa Hussain, ADVANCED FABRICATION PROCESSES FOR SUB-50 nm CMOS, The university of Texas at Austin, December 2005). Referring thereto, when changing the potential difference from 0 V to 3 V, the current density increases about 108 fold for the thickness of 1.5 nm and about 107 fold for the thickness of 2 nm. That is, it can be expected that a change in current density of about 107 fold or more, at least 10⁶ fold or more can be achieved without the help of the control electrode, when the switching insulating layer has a thickness that can provide a pathway for electrons to move by tunneling, channeling, etc.

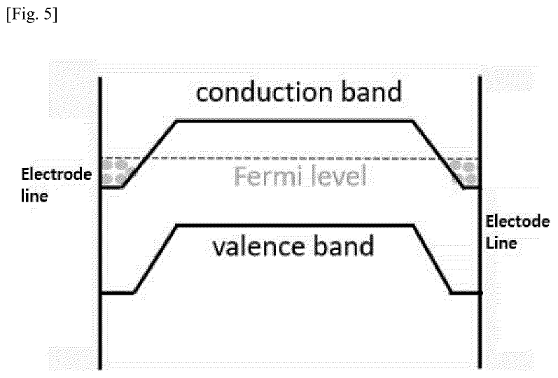

Next, a change in density current according to application of current to the control electrode is described below. FIG. 5 illustrates an energy band inside a switching insulating layer.

The Fermi level lies approximately in the middle of the energy band gap. When the bottom of the conduction band is lower than the Fermi level, electrons are concentrated in the conduction band, and a movement pathway of electrons is formed. As the switching insulating layer has a very small thickness, the electrons concentrated in the conduction band may come from the contact plug (storage node) that the switching insulating layer contacts or from the upper electrode (n+region), as well as from inside the switching insulating layer.

For example, when applying a voltage of about 5 V to the control electrode, the bottom of the conduction band is located below the Fermi level (4.55 V) since the energy band gap of the SiO₂ layer is 9.1 V If a substance having a small energy band gap (e.g., high-k substance), not SiO₂, is used for the switching insulating layer, a movement pathway of electrons may be formed even when the voltage applied to the control electrode is 5 V or less.

Once a movement pathway of electrons is formed in the conduction band, the electrons move from the conduction band, and current flows according to the equation V=IR. A much larger amount of current than the amount of current by tunneling, etc., flows.

Accordingly, it can be easily expected that a change in current density in the conduction band is significantly greater (at least 10⁶ fold or greater) than the change in current density by tunneling.

Next, current by the control electrode and current in a DRAM cell are compared. When the capacitance Cs of a DRAM cell capacitor is 5 fF, a drive voltage is 1 V, and a write time is 10 ns, the current in the DRAM cell can be calculated as below.

$$\frac{copacitor capacitance per cell \times drive voltage}{Write time} = \frac{5 \times 1 {0}^{- 15} F \times 1 V}{10 \times 1 {0}^{- 9} sec} = 0.5 μA \qquad [ Equation 1 ]$$

In FIG. 1.1 in the paper described above, the current density is about 20 μA/cm² when the thickness of the SiO₂ layer is 1.5 nm, and the drive voltage is 1 V. Accordingly, the current (current passing through the switching insulating layer when a voltage is not applied to the control electrode) can be calculated by multiplying said current density by the cross-sectional area of the channel pattern (radius of 7 nm), as indicated below.

$$Gate current density = 20 A / {cm}^{2} \times π \times {( 7 \times 1 {0}^{- 7} cm )}^{2} = 3.0772 \times {10}^{- 11} A \qquad [ Equation 2 ]$$

When multiplying the obtained current value by the change in current density 10⁶ fold, it is calculated as 30.772 μA. This value is greater than 0.5 μA, which is the current in the DRAM cell. Considering the change in current density in the conduction band is significantly greater than the change in current density by tunneling, as described above, it can be confirmed that modification of the conduction band by the control electrode may allow sufficient current flow in the DRAM cell.

The foregoing description of the present specification has been presented for illustrative purposes, and it is apparent to a person having ordinary skill in the art that the present specification can be easily modified into other detailed forms without changing the technical idea or essential features of the present specification. Therefore, it should be understood that the forgoing embodiments are by way of example only, and are not intended to limit the present specification.

For example, each component which has been described as a unitary part can be implemented as distributed parts. Likewise, each component which has been described as distributed parts can also be implemented as a combined part.

The scope of the present specification is presented by the accompanying claims, and it should be understood that all changes or modifications derived from the definitions and scopes of the claims and their equivalents fall within the scope of the present specification.

### DESCRIPTION OF REFERENCE NUMERALS

10: substrate
20: bit line
30: word line
40: channel pattern
40l: lower electrode
40u: upper electrode
50: gate
52: gate insulating pattern
54: gate conducing pattern
60: switching insulating layer
65: spacer layer
70: control electrode
80: contact plug
90: capacitor
100: vertical channel transistor
200: semiconductor device

What is claimed is:

1. A semiconductor device, comprising:
a substrate;
a plurality of bit lines located on the substrate, and disposed parallel to each other in a first horizontal direction at predetermined intervals;
a plurality of word lines located on the bit line, and disposed parallel to each other in a second horizontal direction substantially perpendicular to the first horizontal direction at predetermined intervals;
a plurality of channel patterns arranged in an array on the bit line, the plurality of channel patterns each extending in a vertical direction;
a gate insulating pattern located between the plurality of channel patterns and the plurality of word lines;
a plurality of switching insulating layers each formed on an upper surface of each of the plurality of channel patterns, at least a portion of which has a thickness that an electron can penetrate upon application of a voltage; and
a plurality of control electrodes disposed parallel to each other at predetermined intervals to connect the plurality of switching insulating layers.

2. The semiconductor device of claim 1, wherein the plurality of control electrodes are disposed parallel to each other in the second horizontal direction.

3. The semiconductor device of claim 1, wherein the control electrode has a thickness greater than the thickness of the switching insulating layer.

4. The semiconductor device of claim 1, wherein the switching insulating layer comprises at least one selected from the group consisting of silicon oxide (SiO₂), titanium oxide (TiO₂), aluminum oxide (Al₂O₃), nickel oxide (NiO, NiO₂, Ni₂O₃), copper oxide (Cu₂O, CuO), zirconium oxide (ZrO₂), manganese oxide (MnO, MnO₂, Mn₂O₃, Mn₃O₄, Mn₂O₇), hafnium oxide (HfO₂), tungsten oxide (WO, WO₂, WO₃, W₂O₃), tantalum oxide (Ta₂O₅), niobium oxide (Nb₂O₅) and iron oxide (FeO, Fe₂O₃, Fe₃O₄).

5. The semiconductor device of claim 1, further comprising a spacer layer formed on at least a portion of a side surface of the plurality of channel patterns to electrically insulate the plurality of channel patterns from the plurality of control electrodes.

6. The semiconductor device of claim 1, wherein each of the plurality of channel patterns comprises an upper electrode and a lower electrode, wherein the lower electrode is in contact with the bit line.

7. The semiconductor device of claim 1, further comprising a gate electrode arranged between the word line and the gate insulating pattern.
